(19) United States
(12) Patent Application Publication
(10) Pub. No.: US 2025/0197721 A1
(43) Pub. Date: Jun. 19, 2025

(54) A preparation method of Na+/Cu2+ ions co-doped cesium lead bromide perovskite quantum dots, products and applications thereof

(71) Applicant: CHONGQING UNIVERSITY OF POSTS AND TELECOMMUNICATIONS, Chongqing (CN)

(72) Inventors: Xianju ZHOU, Chongqing (CN); Zhongxiang SHAO, Chongqing (CN); Jie ZHANG, Chongqing (CN); Qianyang CHANG, Chongqing (CN); Li LI, Chongqing (CN); Guotao XIANG, Chongqing (CN); Sha JIANG, Chongqing (CN); Jingfang LI, Chongqing (CN); Guangxin XIE, Chongqing (CN)

(21) Appl. No.: 18/037,770

(22) PCT Filed: Jun. 14, 2022
(86) PCT No.: PCT/CN2022/098630

§ 371 Date: Oct. 14, 2024

(30) Foreign Application Priority Data
Apr. 12, 2022 (CN) 202210381660.3

(51) Int. Cl. C09K 11/66; H10H 29/01; H10H 29/851; H10H 29/854

(52) U.S. Cl. CPC C09K 11/665; H10H 29/0361; H10H 29/0362; H10H 29/8512; H10H 29/854

(57) ABSTRACT

The invention relates to a preparation method of Na⁺/Cu²⁺ ions co-doped cesium lead bromide perovskite quantum dots, products and applications thereof, which belongs to the technical field of modification research of perovskite quantum dots. The invention discloses a preparation method of Na⁺/Cu²⁺ ions co-doped cesium lead bromide (CsPbBr₃) perovskite quantum dots, which adopts lead bromide (PbBr₂), oleic acid (OA), oleylamine (OAm), sodium ion precursors and copper ion precursors for the reaction preparation in octadecene (ODE), in which copper ions (Cu²⁺) and sodium ions (Na⁺) substitute A and B crystal sites in cesium lead bromide (CsPbBr₃) perovskite fluorescent quantum dots respectively. The quantum dots have been effectively improved in photoluminescence quantum yield, thermal stability, etc., and can be used as an active layer to fabricate light emitting diodes which achieve the tuning of emission color from green to blue.

### TECHNICAL FIELD

The invention belongs to the field of modification research of perovskite quantum dots and relates to a preparation method of Na⁺/Cu²⁺ ions co-doped cesium lead bromide perovskite quantum dots, products and applications thereof.

### BACKGROUND

Since the first report of the organic-inorganic lead halide perovskite solar cell, halide perovskite is regarded as a well-deserved star material that its cell efficiency has increased to 25.2% in decades. Halide perovskites have attractive application prospects in photovoltaic, photoelectric detection, lighting, displaying, laser and other optoelectronic fields due to their advantages such as emission wavelength tunability, high optical absorption coefficiency and ultra-long carrier diffusion length. In recent years, through the joint efforts of scholars, perovskite materials have made rapid progress in the field of optoelectronics and biological applications. Compared with other materials, the size effect of halide perovskite quantum dots further narrows the luminescence peak and enhances the photoluminescence efficiency. The rich surface of halide perovskite quantum dots has greatly increased the range of performance control, and many novel optical properties and electrical properties have emerged.

Therefore, halide perovskite quantum dots are used in high-definition display, fluorescent biomarker and electrochemistry with great application potential.

Based on the excellent luminescent properties of halide perovskite quantum dots, they are applied to the display field to achieve a wider color gamut, higher color purity and color rendering index than traditional phosphors. Taking all-inorganic perovskite quantum dots as an example, Zeng Haibo's team prepared high-yield multi-color quantum dot materials at room temperature and obtained a white LED with wide color gamut and tunable color temperature. On this basis, in order to reduce the damage of blue light to the human eye, the researchers prepared single-component white light perovskite quantum dots by doping and self-trapping.

In recent years, some metal ions, such as Mn²⁺, Sn²⁺, Zn²⁺ and K⁺, doped inorganic halide perovskite quantum dots have been shown to enhance their optical properties and stability. However, linking electrons to metal electron ions in electroluminescence remains a difficult task; the radiative transition rates of some ions is much smaller than that of the excitons associated with perovskites. Therefore, metal ion-related photoluminescence will be quenched due to the greatly increased nonradiative transition rate in perovskite quantum dots. This is mainly due to the frequent collisions of injected charge carriers under the action of an electric field, especially for perovskites with high density.

Therefore, in order to realize electroluminescence of metal ions, it is necessary to investigate ions doped halide perovskite quantum dots. In addition, green and red light-emitting diodes based on perovskite quantum dots have been greatly developed, but blue diodes are still facing challenges. This invention explores one method to modify the preparation and composition of cesium lead bromide perovskite quantum dots, which leads to stable blue light-emitting diodes.

### INVENTION CONTENT

In view of this, one of the objects of the present invention is to provide a preparation method of Na⁺/Cu²⁺ ions co-doped cesium lead bromide perovskite quantum dots; the second object of the present invention is to provide a kind of Na⁺/Cu²⁺ ions co-doped cesium lead bromide perovskite quantum dots; the third object of the present invention is to provide an application of Na⁺/Cu²⁺ ions co-doped cesium lead bromide perovskite quantum dots in preparing active layer materials for encapsulating blue light-emitting diodes.

To achieve the above purpose, the present invention provides the following technical solution:
1. A preparation method of Na⁺/Cu²⁺ ions co-doped cesium lead bromide perovskite quantum dots comprises the following steps:
adding lead bromide, oleic acid, oleylamine, sodium ion precursors and copper ion precursors into octadecene, vacuumizing and stirring for 20˜30 min, heating to 100˜120° C., keeping for 20˜30 min to react, then heating up to 150˜160° C. and holding for 15˜30 min to react, then heating up to 175˜190° C. and injecting cesium oleate precursor to react to obtain Na⁺/Cu²⁺ ions co-doped cesium lead bromide perovskite quantum dots. The whole synthesis process is under nitrogen flow.

Preferably, the molar volume ratio of the lead bromide (PbBr₂), oleic acid (OA) and oleylamine (OAm) is (0.4˜1):2:2, mmol:mL:mL;

the molar ratio of the lead bromide (PbBr₂), sodium ion (Na⁺) in the sodium ion precursor and copper ion (Cu²⁺) in the copper ion precursor is 0.4:(0.01˜0.2):(0.01˜0.2);
the molar volume ratio of the lead bromide (PbBr₂) and the octadecene (ODE) is 0.4:(20˜50), mmol:mL;
the molar volume ratio of the lead bromide (PbBr₂) and the cesium oleate precursor is (0.4˜1):1, mmol:mL.

Further preferably, the sodium ion precursor is prepared according to the following method: dissolving sodium bromide (NaBr) in N,N-dimethylformamide, stirring to make it completely dissolved.

Further preferably, the molar volume ratio of the sodium bromide (NaBr) and N,N-dimethylformamide is 0.1:2, mmol:ml.

Further preferably, the copper ion precursor is prepared according to the following method: dissolving copper bromide (CuBr₂) in N,N-dimethylformamide, stirring to make it completely dissolved.

Further preferably, the molar volume ratio of copper bromide (CuBr₂) and N,N-dimethylformamide is 0.1:2, mmol:mL.

Further preferably, the cesium oleate precursor is prepared according to the following method:
adding cesium carbonate (Cs₂CO₃) and oleic acid (OA) to octadecene (ODE), stirring under nitrogen flow for 20˜30 min, then heating up to 100˜120° C., keeping for 20˜30 min to react, then heating up to 150˜160° C. to obtain a brown solution, keeping for 40˜60 min for sufficient reaction.

Preferably, the mass-volume ratio of the cesium carbonate (Cs₂CO₃) and oleic acid (OA) added to octadecene (ODE) is 0.8:2.6:(20˜32), g:mL:mL.
2. The Na⁺/Cu²⁺ ions co-doped cesium lead bromide perovskite quantum dots are prepared according to the above preparation method.
3. The Na⁺/Cu²⁺ ions co-doped cesium lead bromide perovskite quantum dots are used in the application of preparing active layer materials for encapsulating blue light-emitting diodes.

Compared with the prior art, the advantages and beneficial effects of the present invention are: the invention discloses a preparation method of Na⁺/Cu²⁺ ions co-doped cesium lead bromide (CsPbBr₃) perovskite quantum dots, which adopts lead bromide (PbBr₂), oleic acid ((A), oleylamine (OAm), sodium ion precursors and copper ion precursors for the reaction preparation in octadecene (ODE), in which copper ions (Cu²⁺) and sodium ions (Na⁺) substitute A and B crystal sites in cesium lead bromide (CsPbBr₃) perovskite fluorescent quantum dots respectively; the obtained quantum dots have been effectively improved in terms of photoluminescence quantum yield, thermal stability, etc., and can be used as an active layer to encapsulate electroluminescent diodes which achieve the emission color tuning from green to blue through electroluminescence of doped ion-exciton recombination.

Other advantages, objectives and features of the present invention will be illustrated in the following description to some extent, and will be apparent to those skilled in the art based on the following investigation and research to some extent, or can be taught from the practice of the present invention. The objectives and other advantages of the present invention can be realized and obtained through the following description.

### DESCRIPTION OF DRAWINGS

To enable the purpose, the technical solution and the advantages of the present invention to be clearer, the present invention will be preferably described in detail below in combination with the drawings, wherein:

FIG. 1 is the XRD pattern of CsPbBr₃:Cu²⁺, Na⁺ and undoped CsPhBr₃ quantum dots;

FIG. 2 is the TEM image (A) and HR-TEM image (B) of the undoped CsPhBr₃ quantum dots in Embodiment 6, and the TEM image (C) and HR-TEM image (D) of the Cu²⁺ and Na⁺ ions co-doped quantum dots (CsPb_{0.949}Na_{0.033}Cu_{0.018}Br₃) prepared in Embodiment 1;

FIG. 3 is the particle size distribution diagram (A) of the undoped CsPbBr₃ quantum dots in Embodiment 6, and the particle size distribution diagram (B) of the Cu²⁺ and Na⁺ ions co-doped quantum dots (CsPb_{0.949}Na_{0.033}Cu_{0.018}Br₃) prepared in Embodiment 1;

FIG. 4 is the emission spectrum (A) and absorption spectrum (B) of different ratios of Cu²⁺ and Na⁺ ions co-doped CsPbBr₃ quantum dots and undoped CsPbBr₃ quantum dots prepared by the present invention;

In FIG. 5, A is a schematic diagram of the experimental setup, B and D are emission spectra of the undoped CsPbBr₃ quantum dots in Embodiment 6 and the Cu²⁺/Na⁺ co-doped quantum dots (CsPb_{0.949}Na_{0.033}Cu_{0.018}Br₃) in Embodiment 1 in the temperature range of 20˜120° C., C and E are the emission intensity in the 8 thermal cycles of the undoped CsPbBr₃ quantum dots in Embodiment 6 and the Cu²⁺/Na⁺ co-doped quantum dots (CsPb_{0.949}Na_{0.033}Cu_{0.018}Br₃) in Embodiment 1;

In FIG. 6, A is the structural schematic diagram of the light-emitting diodes (PeLEDs) based on Cu²⁺ and Na⁺ co-doped and undoped CsPbBr₃ QDs perovskite, and B is the normalized electroluminescence (EL) and photoluminescence (PL) spectra of the PeLEDs prepared by CsPhBr₃, CsPb_{0.954}Na_{0.034}Cu_{0.012}Br₃ and CsPb_{0.949}Na_{0.033}Cu_{0.018}Br₃, and the inset is the photographs of the fabricated devices on working, C is the electroluminescence (EL) spectra of PeLEDs prepared by CsPbBr₃, CsPb_{0.954}Na_{0.034}Cu_{0.012}Br₃ and CsPb_{0.949}Na_{0.033}Cu_{0.018}Br₃ at different voltages, D is the normalized electroluminescence (EL) and photoluminescence (PL) spectra of the PeLEDs prepared by CsPb_{0.954}Na_{0.032}Cu_{0.023}Br₃, CsPb_{0.933}Na_{0.031}Cu_{0.030}Br₃ and CsPb_{0.918}Na_{0.030}Cu_{0.052}Br₃, and the inset is the photographs of the fabricated devices on working, E is the EL spectra of PeLEDs prepared by CsPb_{0.954}Na_{0.032}Cu_{0.023}Br₃, CsPb_{0.933}Na_{0.031}Cu_{0.030}Br₃ and CsPb_{0.918}Na_{0.030}Cu_{0.052}Br₃ at different voltages;

In FIG. 7, the current density-brightness-voltage (J-L-V) relationship diagram of PeLEDs prepared by CsPbBr₃ (A), CsPb_{0.954}Na_{0.034}Cu_{0.012}Br₃ (B). CsPb_{0.949}Na_{0.33}Cu_{0.018}Br₃ (C), CsPb_{0.954}Na_{0.032}Cu_{0.023}Br₃ (D), CsPb_{0.933}Na_{0.031}Cu_{0.030}Br₃ (E) and CsPb_{0.918}Na_{0.030}Cu_{0.052}Br₃ (F);

In FIG. 8, A is the current density-external quantum efficiency (CE-EQE) characteristic diagram of PeLEDs prepared by undoped CsPbBr₃ quantum dots, and B-F are respectively the current density-external quantum efficiency (CE-EQE) characteristic diagram of PeLEDs prepared by quantum dots CsPb_{0.954}Na_{0.034}Cu_{0.012}Br₃ (B), CsPb_{0.949}Na_{0.033}Cu_{0.018}Br₃ (C) and CsPb_{0.954}Na_{0.032}Cu_{0.023}Br₃ (D), CsPb_{0.933}Na_{0.031}Cu_{0.030}Br₃ (E) and CsPb_{0.918}Na_{0.030}Cu_{0.052}Br₃ (F).

### DETAILED DESCRIPTION

Embodiments of the present invention are described below through specific embodiments. Those skilled in the art can understand other advantages and effects of the present invention easily through the disclosure of the description. The present invention can also be implemented or applied through additional different specific embodiments. All details in the description can be modified or changed based on different perspectives and applications without departing from the spirit of the present invention. It should be noted that the figures provided in the following embodiments only exemplarily explain the basic conception of the present invention, and if there is no conflict, the following embodiments and the features in the embodiments can be mutually combined.

The present invention will be further described in detail below in conjunction with the accompanying drawings:

### Embodiment 1

A Na⁺/Cu²⁺ ions co-doped cesium lead bromide (CsPbBr₃) perovskite quantum dot is prepared according to the following method:
(1) Preparation of cesium oleate precursor: put 0.8 g of cesium carbonate, 2.6 ml of oleic acid and 32 ml of octadecene in a 100 mL three-necked flask, stir under nitrogen flow for 20 min, heat to 120° C., and hold for 30 min to react, heat the mixture to 160° C. to obtain a brown solution, keep for 60 min for sufficient reaction to obtain the cesium oleate precursor, and then preheat to 100° C. for use.
(2) Preparation of sodium ion precursor and copper ion precursor: add 0.1 mmol sodium bromide (NaBr) to 2 mL of DMF solution, stir well until dissolved to obtain sodium ion precursor; add 0.1 mmol copper bromide (CuBr₂) to 2 ml of DMF solution, and stir well until dissolved to obtain sodium ion precursor.
(3) Put 0.4 mmol of lead bromide, 2 mL of oleic acid, 2 mL of oleylamine and 40 ml of octadecene into a 100 ml three-necked flask, and then add 0.04 ml of the sodium ion precursor in step (2) and 0.08 mL of the copper ion precursor in step (2) into the three-necked flask, evacuate and then introduce with nitrogen, stir for 20 min, heat to 120° C. for 30 min for reaction, then heat to 160° C. and hold for 30 min for reaction, and then heat to 190° C. and inject into 1 ml of the cesium oleate precursor obtained in step (1) for reaction to get quantum dots (CsPb_{0.949}Na_{0.033}Cu_{0.018}Br₃).

### Embodiment 2

A Na⁺/Cu²⁺ ions co-doped cesium lead bromide (CsPbBr₃) perovskite quantum dot is prepared according to the following method:
(1) Preparation of cesium oleate precursor: put 0.8 g of cesium carbonate, 2.6 mL of oleic acid and 32 ml of octadecene in a 100 mL three-necked flask, stir under nitrogen flow for 20 min, heat to 120° C., and hold for 30 min to react, heat the mixture to 160° C. to obtain a brown solution, keep for 60 min for sufficient reaction to obtain the cesium oleate precursor, and then preheat to 100° C. for use.
(2) Preparation of sodium ion precursor and copper ion precursor: add 0.1 mmol sodium bromide (NaBr) to 2 ml of DMF solution, stir well until dissolved to obtain sodium ion precursor; add 0.1 mmol copper bromide (CuBr₂) to 2 ml of DMF solution, and stir well until dissolved to obtain sodium ion precursor.
(3) Put 0.4 mmol of lead bromide, 2 mL of oleic acid, 2 ml of oleylamine and 40 ml of octadecene into a 100 ml three-necked flask, and then add 0.04 mL of the sodium ion precursor in step (2) and 0.04 ml of the copper ion precursor in step (2) into the three-necked flask, evacuate and then introduce with nitrogen, stir for 20 min, heat to 120° C. for 30 min for reaction, then heat to 160° C. and hold for 30 min for reaction, and then heat to 190° C. and inject into 1 ml of the cesium oleate precursor obtained in step (1) for reaction to get quantum dots (CsPb_{0.954}Na_{0.031}Cu_{0.012}Br₃).

### Embodiment 3

A Na⁺/Cu²⁺ ions co-doped cesium lead bromide (CsPbBr₃) perovskite quantum dot is prepared according to the following method:
(1) Preparation of cesium oleate precursor: put 0.8 g of cesium carbonate, 2.6 ml of oleic acid and 32 mL of octadecene in a 100 ml three-necked flask, stir under nitrogen flow for 20 min, heat to 120° C., and hold for 30 min to react, heat the mixture to 160° C. to obtain a brown solution, keep for 60 min for sufficient reaction to obtain the cesium oleate precursor, and then preheat to 100° C. for use.
(2) Preparation of sodium ion precursor and copper ion precursor: add 0.1 mmol sodium bromide (NaBr) to 2 ml of DMF solution, stir well until dissolved to obtain sodium ion precursor; add 0.1 mmol copper bromide (CuBr₂) to 2 ml of DMF solution, and stir well until dissolved to obtain sodium ion precursor.
(3) Put 0.4 mmol of lead bromide, 2 mL of oleic acid, 2 ml of oleylamine and 40 ml of octadecene into a 100 ml three-necked flask, and then add 0.04 ml of the sodium ion precursor in step (2) and 0.12 mL of the copper ion precursor in step (2) into the three-necked flask, evacuate and then introduce with nitrogen, stir for 20 min, heat to 120° C. for 30 min for reaction, then heat to 160° C. and hold for 30 min for reaction, and then heat to 190° C. and inject into 1 ml of the cesium oleate precursor obtained in step (1) for reaction to get quantum dots (CsPb_{0.945}Na_{0.032}Cu_{0.023}Br₃).

### Embodiment 4

A Na⁺/Cu²⁺ ions co-doped cesium lead bromide (CsPbBr₃) perovskite quantum dot is prepared according to the following method:
(1) Preparation of cesium oleate precursor: put 0.8 g of cesium carbonate, 2.6 ml of oleic acid and 32 ml of octadecene in a 100 ml three-necked flask, stir under nitrogen flow for 20 min, heat to 120° C., and hold for 30 min to react, heat the mixture to 160° C. to obtain a brown solution, keep for 60 min for sufficient reaction to obtain the cesium oleate precursor, and then preheat to 100° C. for use.
(2) Preparation of sodium ion precursor and copper ion precursor: add 0.1 mmol sodium bromide (NaBr) to 2 mL of DMF solution, stir well until dissolved to obtain sodium ion precursor; add 0.1 mmol copper bromide (CuBr₂) to 2 ml of DMF solution, and stir well until dissolved to obtain sodium ion precursor.
(3) Put 0.4 mmol of lead bromide, 2 mL of oleic acid, 2 ml of oleylamine and 40 ml of octadecene into a 100 mL three-necked flask, and then add 0.04 ml of the sodium ion precursor in step (2) and 0.16 ml of the copper ion precursor in step (2) into the three-necked flask, evacuate and then introduce with nitrogen, stir for 20 min, heat to 120° C. for 30 min for reaction, then heat to 160° C. and hold for 30 min for reaction, and then heat to 190° C. and inject into 1 ml of the cesium oleate precursor obtained in step (1) for reaction to get quantum dots (CsPb_{0.933}Na_{0.031}Cu_{0.030}Br₃).

### Embodiment 5

A Na⁺/Cu²⁺ ions co-doped cesium lead bromide (CsPhBr₃) perovskite quantum dot is prepared according to the following method:
(1) Preparation of cesium oleate precursor: put 0.8 g of cesium carbonate, 2.6 mL of oleic acid and 32 ml of octadecene in a 100 ml three-necked flask, stir under nitrogen flow for 20 min, heat to 120° C., and hold for 30 min to react, heat the mixture to 160° C. to obtain a brown solution, keep for 60 min for sufficient reaction to obtain the cesium oleate precursor, and then preheat to 100° C. for use.
(2) Preparation of sodium ion precursor and copper ion precursor: add 0.1 mmol sodium bromide (NaBr) to 2 mL of DMF solution, stir well until dissolved to obtain sodium ion precursor; add 0.1 mmol copper bromide (CuBr₂) to 2 mL of DMF solution, and stir well until dissolved to obtain sodium ion precursor.
(3) Put 0.4 mmol of lead bromide, 2 ml of oleic acid, 2 ml of oleylamine and 40 ml of octadecene into a 100 ml three-necked flask, and then add 0.04 mL of the sodium ion precursor in step (2) and 0.20 mL of the copper ion precursor in step (2) into the three-necked flask, evacuate and then introduce with nitrogen, stir for 20 min, heat to 120° C. for 30 min for reaction, then heat to 160° C. and hold for 30 min for reaction, and then heat to 190° C. and inject into 1 ml of the cesium oleate precursor obtained in step (1) for reaction to get quantum dots (CsPb_{0.918}Na_{0.030}Cu_{0.052}Br₃).

### Embodiment 6

A cesium lead bromide (CsPbBr₃) perovskite quantum dot is prepared according to the following method:
(1) Preparation of cesium oleate precursor: put 0.8 g of cesium carbonate, 2.6 ml of oleic acid and 32 ml of octadecene in a 100 ml three-necked flask, stir under nitrogen flow for 20 min, heat to 120° C., and hold for 30 min to react, heat the mixture to 160° C. to obtain a brown solution, keep for 60 min for sufficient reaction to obtain the cesium oleate precursor, and then preheat to 100° C. for use.
(2) Put 0.4 mmol of lead bromide, 2 mL of oleic acid, 2 mL of oleylamine and 40 mL of octadecene into a 100 ml three-necked flask, evacuate and then introduce with nitrogen, stir for 20 min, heat to 120° C. for 30 min for reaction, then heat to 160° C. and hold for 30 min for reaction, and then heat to 190° C. and inject into 1 mL of the cesium oleate precursor obtained in step (1) for reaction to get CsPbBr₃ quantum dots.

### Embodiment 7

The CsPbBr₃ perovskite quantum dots prepared in Embodiment 1˜6 with different ratios of Cu²⁺ and Na⁺ ions co-doped and undoped CsPbBr₃ quantum dots are used to form different products;

The CsPbBr₃ perovskite quantum dots substituted with different ratios of Cu²⁺ and Na⁺ ions replacing A and B sites and the undoped CsPhBr₃ quantum dots prepared in Embodiment 1˜6 are added to 5 mL of ethyl acetate. After centrifugation at 6000 rpm for 8 min using a centrifuge, the supernatant is poured out, and the quantum dots at the bottom of the centrifuge tube are re-dispersed into n-hexane. This step is repeated three times, and then a part of the precipitate is dispersed in toluene to prepare a film sample, a part of the precipitate was dispersed in n-hexane to prepare a liquid sample, and a part of the precipitate was dried to prepare a powder sample.

### Performance Testing

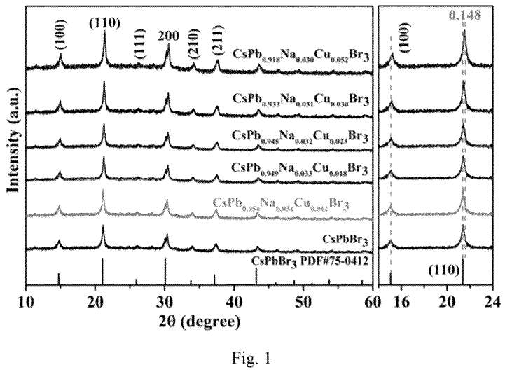

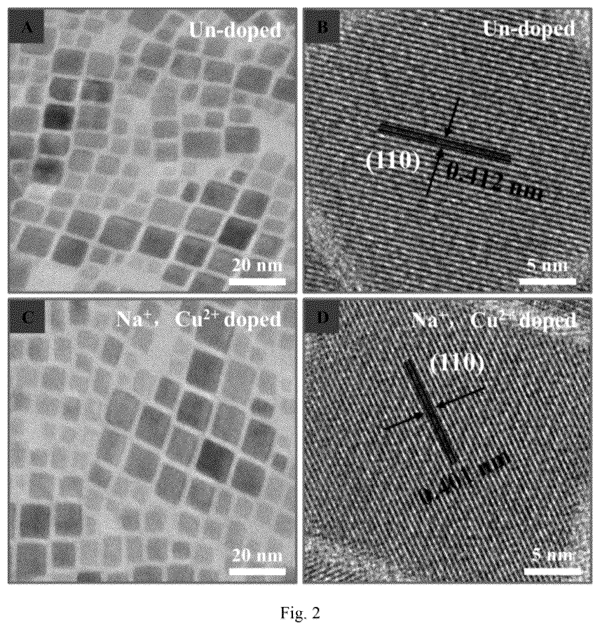

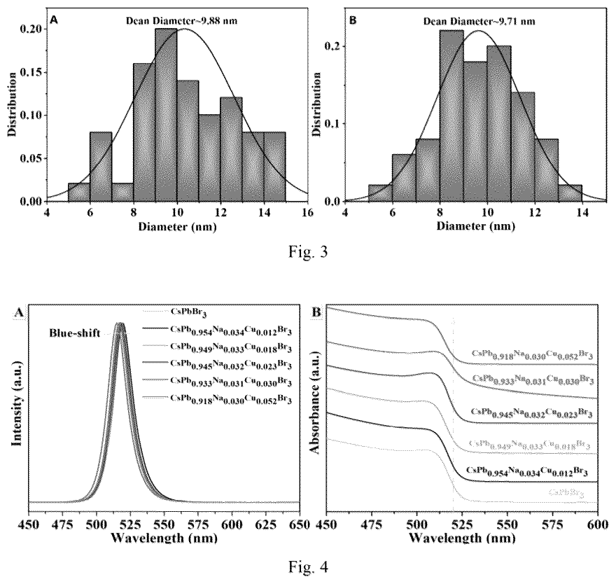

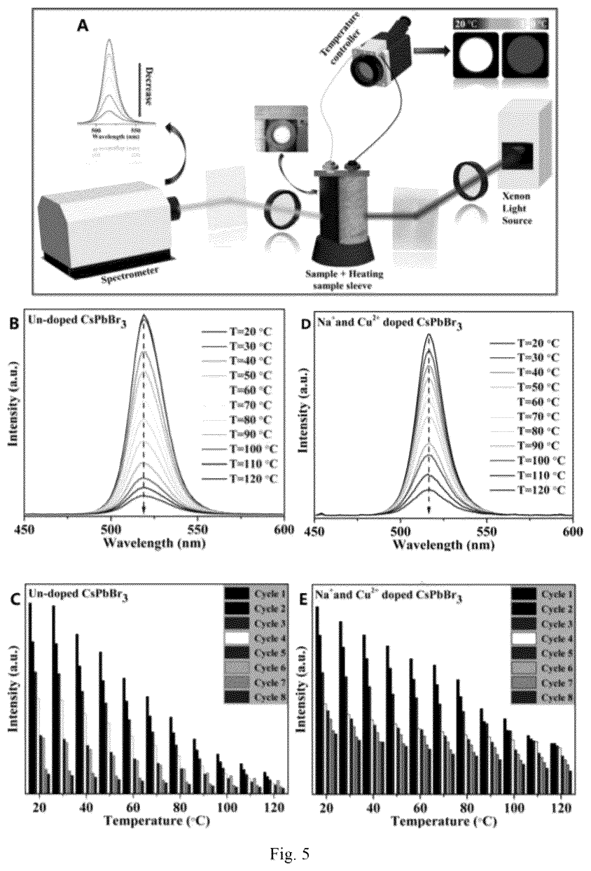

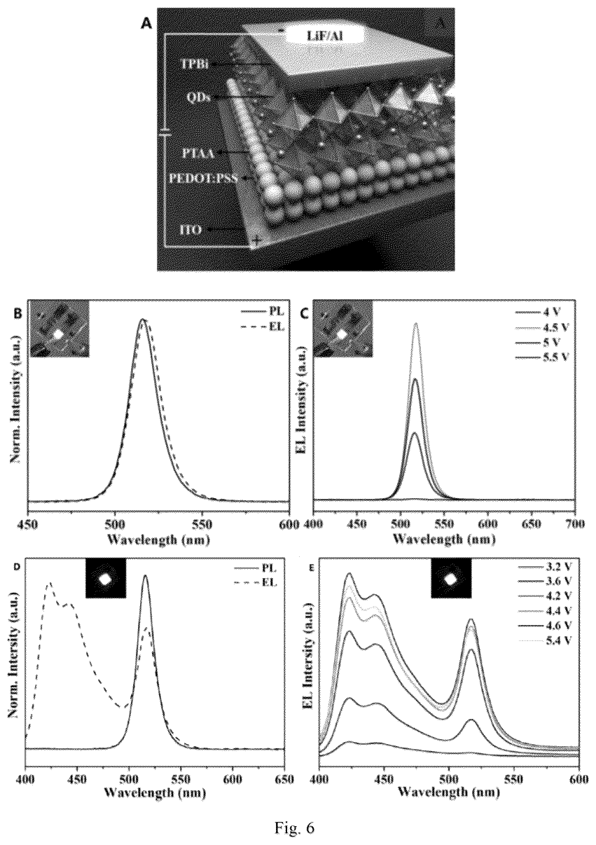

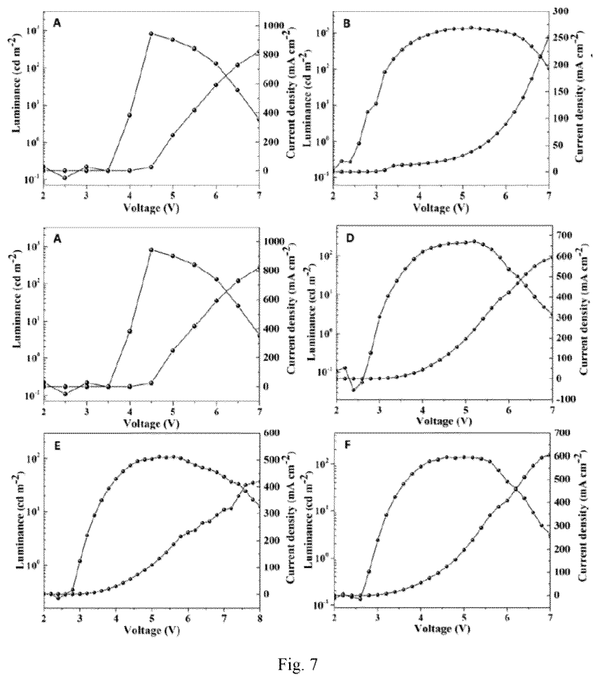

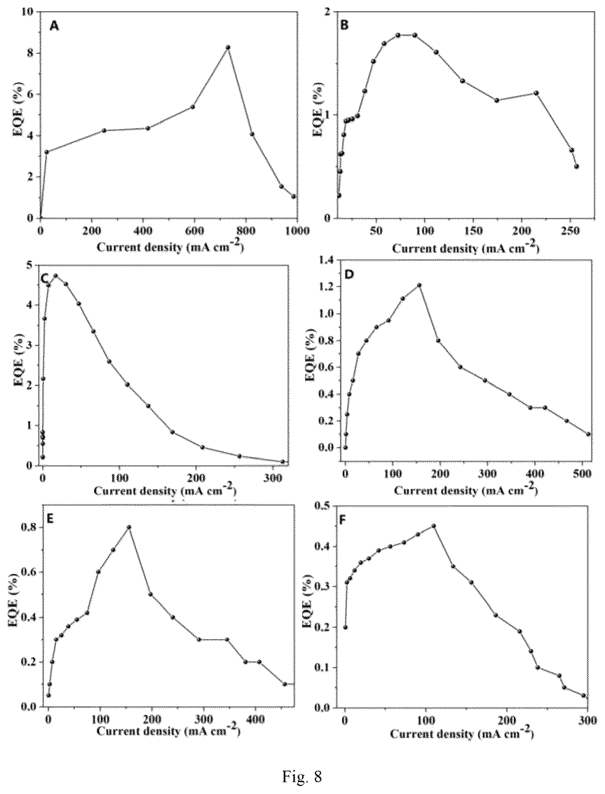

1. The quantum dots prepared in Embodiment 1˜6 were tested by X-ray diffraction, and the results are shown in FIG. 1. Since the ionic radius (˜79 pm) of copper ion (Cu²⁺) is much smaller than the ionic radius (˜133 pm) of lead ion (Pb²⁺), the ionic radius (˜116 pm) of sodium ion (Na⁺) is also much smaller than the ionic radius (˜167 pm) of cesium ions (Cs⁺), the octahedral contraction of cesium lead bromide (CsPbBr₃) is induced by doping sodium ions (Na⁺) and copper ions (Cu²⁺) into cesium lead bromide (CsPbBr₃). According to the Bragg's law: 2d sin θ=kλ, when part of lead ions (Pb²⁺) are substituted by copper ions (Cu²⁺) and part of cesium ions (Cs⁺) are replaced by sodium ions (Na⁺) ions, the interplanar spacing d will become smaller where A is a constant value, and the diffraction angle θ will become larger.
2. The liquid samples prepared from the perovskite quantum dots (CsPb_{0.545}Na_{0.033}Cu_{0.018}Br₃) in Embodiment 1 and the undoped quantum dots (CsPbBr₃) in Embodiment 6 were analyzed by transmission electron microscopy and high-resolution transmission electron microscopy, and the results are shown in FIG. 2 (A and B are TEM and HR-TEM images of undoped CsPbBr₃ quantum dots, C and D are TEM and HR-TEM images of CsPb_{0.949}Na_{0.033}Cu_{0.018}Br₃ quantum dots). It can be seen from (A) and (C) that the doped perovskite quantum dots (CsPb_{0.949}Na_{0.033}Cu_{0.018}Br₃) in Embodiment 1 and the undoped quantum dots (CsPbBr₃) in Embodiment 6 have similar morphologies both showing a cubic shape; from the high-resolution transmission electron microscopes (B) and (D), it can be seen that the interplanar distances (110) of the doped perovskite quantum dots (CsPb_{0.49}Na_{0.033}Cu_{0.019}Br₃) in Embodiment 1 and the undoped quantum dots (CsPbBr₃) in Embodiment 6 are 0.401 nm and 0.412 nm, respectively.
3. The doped perovskite quantum dots (CsPb_{0.949}Na_{0.033}Cu_{0.018}Br₃) in Embodiment 1 and the undoped quantum dots (CsPbBr₃) in Embodiment 6 were analyzed by particle size analysis software, and the results are shown in FIG. 3. (A is the particle size distribution of undoped quantum dots (CsPbBr₃), and B is the particle size distribution of the doped perovskite quantum dots (CsPb_{0.949}Na_{0.033}Cu_{0.019}Br₃). It can be seen from FIG. 3 that the average particle size of the doped perovskite quantum dots (CsPb_{0.949}Na_{0.033}Cu_{0.018}Br₃) in Embodiment 1 and the undoped quantum dots (CsPbBr₃) in Embodiment 6 is 9.88 mm and 9.71 nm, respectively. Lattice shrinkage of CsPbBr₃ perovskite quantum dots doped with sodium ions (Na⁺) and copper ions (Cu²⁺) indicates that part of the larger lead ions (Pb²⁺) (˜133 pm) are replaced by smaller copper ions (Cu²⁺) (˜79 pm), and larger cesium ions (Cs⁺) (˜167 pm) were replaced by smaller sodium ions (Na⁺) (˜116 pm), which is consistent with the XRD results.
4. The liquid samples prepared from the CsPbBr₃ perovskite quantum dots substituted with different ratios of Cu²⁺ and Na⁺ ions and the undoped perovskite quantum dots (CsPbBr₃) in Embodiment 1˜6 were subjected to ultraviolet light radiation, and the results of the absorption and emission spectrum tests are shown in FIG. 4, where A is the emission spectrum and B is the absorption spectrum. As can be seen from A, the liquid sample of undoped perovskite quantum dots (CsPbBr₃) in Embodiment 6 exhibits typical exciton emission at 520 nm; the photoemission spectra of CsPbBr₃ perovskite quantum dots doped with different ratios of Cu²⁺ and Na⁺ ions also show typical exciton emission, and their emission peaks gradually blue-shift 1˜5 nm with the increase of doping concentration which indicates that the doping of Na⁺/Cu²⁺ ions will affect the local electronic configuration and energy band of cesium lead bromide perovskite quantum dots (CsPbBr₃). In B, it can be seen that the band-edge absorption of Na and Cu co-doped cesium lead calcium bromide (CsPhBr₃:Na⁺/Cu²⁺) quantum dots slightly shifts towards blue with increasing copper ion (Cu²⁺) concentration. The reason for this phenomenon is the effect of doping sodium ions (Na⁺) and copper ions (Cu²⁺) on the band gap of cesium lead bromide (CsPbBr₃) perovskite quantum dots.
5. The emission spectra of thin film samples prepared from the doped perovskite quantum dots (CsPb_{0.949}Na_{0.033}Cu_{0.018}Br₃) in Embodiment 1 and the undoped quantum dots (CsPbBr₃) in Embodiment 6 were tested at variable temperatures in the range of 20˜120° C., and the results are as shown in FIG. 5 (A is a schematic diagram of the experimental setup, B and D are the temperature-dependent emission spectra of the Cu²⁺ and Na⁺ ions co-doped perovskite quantum dots (CsPb_{0.949}Na_{0.033}Cu_{0.018}Br₃) in Embodiment 1 and the undoped CsPbBr₃ quantum dots in Embodiment 6 in the range of 20˜120° C., respectively. C and E are 8 thermal cycle test charts of the undoped quantum dots (CsPbBr₃) in Embodiment 6 and the Cu²⁺/Na⁺ co-doped perovskite quantum dots (CsPb_{0.49}Na_{0.033}Cu_{0.019}Br₃) in Embodiment 1, respectively. In B and C, it can be seen that the photoluminescence intensity of undoped quantum dots (CsPbBr₃) and doped perovskite quantum dots (CsPb_{0.949}Na_{0.033}Cu_{0.018}Br₃) gradually decreases with increasing temperature. At the end of the first heating cycle of undoped quantum dots (CsPbBr₃), it sees a 70% emission decay but only about 50% emission attenuation occurs in the doped perovskite quantum dots (CsPb_{0.949}Na_{0.033}Cu_{0.018}Br₃). It can be seen from C and E that after 8 thermal cycles, the emission spectrum intensity of undoped perovskite quantum dots (CsPbBr₃) dropped to about 10% of the initial value, but the emission intensity of the doped perovskite quantum dots (CsPb_{0.949}Na_{0.033}Cu_{0.018}Br₃) remains at about 40% of the initial value. Obviously, this phenomenon reflects the decisive effect of Na⁺/Cu²⁺ ions co-doping on improving the thermal stability of cesium lead bromide perovskite quantum dots (CsPbBr₃).
6. The liquid samples prepared from the doped perovskite quantum dots substituted with different proportions of Cu²⁺ and Na⁺ ions co-doped perovskite quantum dots and the undoped perovskite quantum dots (CsPbBr₃) in Embodiment 1˜6 were used to prepare the active layer of the encapsulated light-emitting diode, and then the performance of the corresponding diode was tested. In FIG. 6. A is the schematic structural diagram of PeLED based on Cu²⁺ and Na⁺ co-doped and undoped CsPbBr₃ QDs, B is the normalized electroluminescence (EL) and photoluminescence (PL) spectra of PeLEDs prepared from CsPbBr₃ in Embodiment 6, CsPb_{0.954}Na_{0.034}Cu_{0.012}Br₃ in Embodiment 1 and CsPb_{0.949}Na_{0.033}Cu_{0.018}Br₃ in Embodiment 2 (the inset is the photographs of the prepared device when it is working), C is the EL spectra of PeLEDs prepared from CsPbBr₃ in Embodiment 6, CsPb_{0.954}Na_{0.034}Cu_{0.012}Br₃ in Embodiment 1 and CsPb_{0.949}Na_{0.033}Cu_{0.018}Br₃ in Embodiment 2 at different voltages, D is the normalized EL and PL spectra of PeLEDs prepared from CsPb_{0.945}Na_{0.032}Cu_{0.023}Br₃. CsPb_{0.933}Na_{0.031}Cu_{0.030}Br₃ and CsPb_{0.918}Na_{0.030}Cu_{0.052}Br₃ quantum dots in Embodiment 3˜5 (the inset is the photographs of the prepared device when it works), E is the EL spectra of PeLEDs prepared from quantum dots of CsPb_{0.945}Na_{0.032}Cu_{0.023}Br₃. CsPb_{0.933}Na_{0.031}Cu_{0.030}Br₃ and CsPb_{0.918}Na_{0.030}Cu_{0.052}Br₃ quantum dots in Embodiment 3˜5 at different voltages. It can be seen from FIG. 6 that with the further increase of the doping concentration, the recombination of excitons and doping ions or the recombination between electrons and doping ions occurs, and a broad-band emission is formed in the EL spectrum, that is, the realization of variation from green to blue; bright blue light emission is clearly observed in the inset.
7. In FIG. 7, A is the current density-brightness-voltage (J-L-V) relationship diagram of the PeLED prepared by undoped quantum dots (CsPbBr₃), and B-F are the current density-brightness-voltage (J-L-V) graph of the PeLEDs prepared by quantum dots of CsPb_{0.954}Na_{0.034}Cu_{0.012}Br₃ (B), CsPb_{0.949}Na_{0.033}Cu_{0.018}Br₃ (C), CsPb_{0.954}Na_{0.032}Cu_{0.023}Br₃ (D), CsPb_{0.933}Na_{0.031}Cu_{0.030}Br₃ (E) and CsPb_{0.918}Na_{0.030}Cu_{0.052}Br₃ (F). It can be seen from FIG. 7 that the doping concentration will affect the performance of the device which can improve the turn-on voltage, circuit density and brightness of the device. When the doping concentration is further increased, the emission of excitons and doping ions will appear in the device. After the recombination of excitons and doping ions or the recombination between electrons and doping ions occurs inside the device, a new charged layer is formed, which changes the emission color. At the same time, after a large number of electrons are injected, the electrons and ions move faster which speeds up the carrier migration rate, might leading to leakage of the device or breakdown of the active layer, making the performance of the device worse. Therefore, there is an optimal doping concentration of sodium and copper ions, not “the more, the better”.
8. In FIG. 8, A is the current density-external quantum efficiency (CE-EQE) characteristic diagram of the PeLED prepared by undoped CsPbBr₃ quantum dots, and B-F are the current density-external quantum efficiency (CE-EQE) characteristic diagram of the PeLED prepared by the quantum dots CsPb_{0.954}Na_{0.034}Cu_{0.012}Br₃ (B), CsPb_{0.949}Na_{0.033}Cu_{0.018}Br₃ (C), CsPb_{0.954}Na_{0.032}Cu_{0.023}Br₃ (D), CsPb_{0.933}Na_{0.031}Cu_{0.030}Br₃ (E) and CsPb_{0.918}Na_{0.030}Cu_{0.052}Br₃ (F). FIG. 8 shows the corresponding relationship between the current density and the external quantum efficiency of PeLEDs prepared by undoped and doped CsPbBr₃ quantum dots with different concentrations of Cu²⁺ and Na⁺. Therefore, doping in semiconductors is an effective strategy to improve device performance due to the increase in conductivity, the decrease in electrode implantation barrier and the change in Fermi level.

In summary, the invention discloses a preparation method of Na⁺/Cu²⁺ ions co-doped cesium lead bromide (CsPbBr₃) perovskite quantum dots, which adopts lead bromide (PhBr₂), oleic acid (OA), oleylamine (OAm), sodium ion precursors and copper ion precursors for the reaction preparation in octadecene (ODE), in which copper ions (Cu²⁺) and sodium ions (Na⁺) co-doped cesium lead bromide (CsPbBr₃) perovskite fluorescent quantum dots; the final product has been effectively improved in terms of photoluminescence quantum yield, thermal stability, etc., and can be used as an active layer to encapsulate electroluminescent diodes which achieve the emission color tuning from green to blue through electroluminescence of doped ion-exciton recombination.

The above descriptions are only examples of the invention, and are not used to limit the protection scope of the invention. For those skilled in the art, the application can have various modifications and changes. Any modification, equivalent replacement, improvement, etc. made within the spirit and principle of this invention shall be included in the protection scope of this invention.

1. A preparation method of Na⁺/Cu²⁺ ions co-doped cesium lead bromide perovskite quantum dots, characterized in that the preparation method comprises the following steps:
adding an appropriate amount of lead bromide, oleic acid, oleylamine, sodium ion precursors and copper ion precursors into octadecene, then vacuumizing and introducing nitrogen, stirring for 20˜30 min, heating to 100˜120° C., keeping for 20˜30 min to react, then heating up to 150˜160° C. and holding for 15˜30 min to react, then heating up to 175˜190° C. and injecting cesium oleate precursor to react and obtain Na⁺/Cu²⁺ ions co-doped cesium lead bromide perovskite quantum dots.

2. The preparation method according to claim 1, characterized in that the molar volume ratio of the lead bromide, oleic acid and oleylamine is (0.4˜1):2:2, mmol:mL:mL;
the molar ratio of Pb²⁺, Na⁺ and Cu²⁺ is 0.4:(0.01˜0.2):(0.01˜0.2);
the molar volume ratio of the lead bromide and the octadecene is 0.4:(20˜50), mmol:ml;
the molar volume ratio of the lead bromide and the cesium oleate precursor is (0.4˜1):1, mmol:mL.

3. The preparation method according to claim 2, characterized in that the sodium ion precursor is prepared according to the following method: dissolving sodium bromide in N,N-dimethylformamide, stirring to make it completely dissolved.

4. The preparation method according to claim 3, characterized in that the molar volume ratio of the sodium bromide and N,N-dimethylformamide is 0.1:2, mmol:mL.

5. The preparation method according to claim 2, characterized in that the copper ion precursor is prepared according to the following method: dissolving copper bromide in N,N-dimethylformamide, stirring to make it completely dissolved.

6. The preparation method according to claim 5, characterized in that the molar volume ratio of copper bromide and N,N-dimethylformamide is 0.1:2, mmol:mL.

7. The preparation method according to claim 2, characterized in that the cesium oleate precursor is prepared according to the following method:
adding cesium carbonate and oleic acid to octadecene, stirring under nitrogen flow for 20˜30 min, then heating up to 100˜120° C., keeping for 20˜30 min to react, then heating up to 150˜160° C. to obtain a brown solution, keeping for 40˜60 min for subsequent reaction.

8. The preparation method according to claim 7, characterized in that the mass-volume ratio of the cesium carbonate and oleic acid added to octadecene is 0.8:2.6:(20˜32), g:mL:mL.

9. The preparation method according to any one of claim 1 to claim 8, characterized in that the preparation method prepares Na⁺/Cu²⁺ ions co-doped cesium lead bromide perovskite quantum dots.

10. The Na⁺/Cu²⁺ ions co-doped cesium lead bromide perovskite quantum dots according to claim 9 are used in the application of preparing active layer materials for encapsulating light-emitting diodes which achieve the tuning of emission color from green to blue.
